(19) United States
(12) Patent Application Publication
(10) Pub. No.: US 2026/0029487 A1
(43) Pub. Date: Jan. 29, 2026

(54) BATTERY DIAGNOSTIC APPARATUS AND PROGRAM

(71) Applicant: DENSO CORPORATION, Kariya-city (JP)

(72) Inventors: Yuki Hori, Kariya-city (JP); Yuichi Nishizawa, Kariya-city (JP); Masaki Uchiyama, Kariya-city (JP)

(73) Assignee: DENSO CORPORATION, Kariya-city (JP)

(21) Appl. No.: 19/350,511

(22) Filed: Oct. 6, 2025

Related U.S. Application Data
(63) Continuation of application No. PCT/JP2024/009290, filed on Mar. 11, 2024.

(30) Foreign Application Priority Data
Apr. 6, 2023 (JP) 2023-062177

(51) Int. Cl. G01R 31/392; G01R 31/374; G01R 31/3842; G01R 31/396; H01M 10/42; H01M 10/48

(52) U.S. Cl. CPC G01R 31/392; G01R 31/374; G01R 31/3842; G01R 31/396; H01M 10/425; H01M 10/482; H01M 10/486; H01M 2010/4271

(57) ABSTRACT

A battery system includes an assembled battery including unit cells and a detection unit provided in at least one unit cell. A battery diagnostic apparatus calculates a state-of-health based on a parameter for degradation diagnosis detected by the detection unit for at least one unit cell, and calculates a change amount of a state-of-charge caused by energization, for the unit cells. When a unit cell of which the state-of-health is calculated is a first unit cell and a unit cell of which the state-of-health is not calculated is a second unit cell, the battery diagnostic apparatus calculates, as the state-of-health of the second unit cell, a value obtained by multiplying a change amount ratio that is a ratio of the change amount of the state-of-charge of the first unit cell to the change amount of the state-of-charge of the second unit cell by the state-of-health of the first unit cell.

### CROSS-REFERENCE TO RELATED APPLICATION

The present application is a continuation application of International Application No. PCT/JP2024/009290, filed on Mar. 11, 2024, which claims priority to Japanese Patent Application No. 2023-062177, filed on Apr. 6, 2023. The contents of these applications are incorporated herein by reference in their entirety.

### BACKGROUND

The present disclosure relates to a battery diagnostic apparatus and a program.

In storage batteries, a full-charge capacity decreases in accompaniment with degradation. Therefore, a technology in which a state-of-health (SOH) is calculated as a degradation index indicating a degree of degradation of a storage battery is known.

### SUMMARY

An aspect of the present disclosure provides a battery diagnostic apparatus that is applicable to a battery system that includes an assembled battery that includes a plurality of unit cells connected in series and a detection unit that is provided in at least one unit cell among the plurality of unit cells and detects a parameter for degradation diagnosis. The battery diagnostic apparatus calculates a state-of-health indicating a degree of degradation of each unit cell. The battery diagnostic apparatus acquires the parameter detected by the detection unit for at least one unit cell among the plurality of unit cells and calculates the state-of-health based on the parameter. The battery diagnostic apparatus calculates a change amount of a state-of-charge caused by energization, for the plurality of unit cells. When a unit cell of which the state-of-health is calculated by the battery diagnostic apparatus among the plurality of unit cells is a first unit cell and a unit cell of which the state-of-health is not calculated among the plurality of unit cells is a second unit cell, the battery diagnostic apparatus calculates a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell.

### BRIEF DESCRIPTION OF THE DRAWINGS

In the accompanying drawings:

FIG. 1 is a diagram illustrating a configuration of a battery system;

FIG. 2 is a diagram illustrating a correlation map used to calculate an SOH;

FIG. 3 is a diagram illustrating voltage-SOC characteristics of a unit cell;

FIG. 4 is a flowchart illustrating steps for calculating the SOH of a unit cell;

FIG. 5 is a diagram illustrating a configuration of a variation example of the battery system;

FIG. 6 is a diagram illustrating a configuration of a variation example of the battery system;

FIG. 7 is a diagram illustrating a configuration of a battery system according to a second embodiment;

FIG. 8 is a flowchart illustrating an SOH calculation process according to the second embodiment;

FIG. 9 is a flowchart illustrating an SOH calculation process according to a third embodiment;

FIG. 10 is a diagram illustrating a voltage-SOC characteristic line of a unit cell; and;

FIG. 11 is a diagram illustrating a configuration of a battery system according to another embodiment.

### DESCRIPTION OF THE EMBODIMENTS

Conventionally, a technology in which a secondary battery is provided with a temperature sensor that detects battery temperature and a sensor that detects impedance (internal resistance) in the secondary battery, and a capacity of the secondary battery is estimated based on the battery temperature and the impedance has been disclosed (see, for example, JP 2020-034383 A).

Incidentally, in an assembled battery having a plurality of unit cells, the temperature and the impedance are required to be detected for each unit cell to calculate the SOH of each unit cell. However, if all unit cells are provided with the sensors that detect the temperature and the impedance, increase in cost and increase in size become a concern.

It is thus desired to provide a battery diagnostic apparatus and a program capable of suitably calculating an SOH of each unit cell contained in an assembled battery.

An aspect of the present disclosure provides a battery diagnostic apparatus that is applicable to a battery system including an assembled battery that includes a plurality of unit cells connected in series and a detection unit that is provided in at least one unit cell among the plurality of unit cells and detects a parameter for degradation diagnosis, the battery diagnostic apparatus calculating a state-of-health indicating a degree of degradation of each unit cell. The battery diagnostic apparatus includes: a first calculation unit that acquires the parameter detected by the detection unit for at least one unit cell among the plurality of unit cells and calculates the state-of-health based on the parameter; a second calculation unit that calculates a change amount of a state-of-charge caused by energization, for the plurality of unit cells; and a third calculation unit that, when a unit cell of which the state-of-health is calculated by the first calculation unit among the plurality of unit cells is a first unit cell and a unit cell of which the state-of-health is not calculated is a second unit cell, calculates a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell.

In the assembled battery, a change amount of a remaining capacity of each unit cell caused by energization corresponds to a product of the SOH, a change amount of the state-of-charge (SOC), and a reference full-charge capacity of the unit cell. In this case, in the assembled battery in which the plurality of unit cells are connected in series, the change amounts of the remaining capacities of the unit cells are all the same even if the SOH of the unit cells differs. Therefore, the product of the SOH and the SOC change amount is the same for all unit cells. In light of this point, the unit cell of which the SOH is calculated based on the parameter for degradation diagnosis among the plurality of unit cells is the first unit cell, and the unit cell of which the SOH is not calculated is the second unit cell. In addition, a value obtained by multiplying a change amount ratio that is a ratio of the SOC change amount of the first unit cell to the SOC change amount of the second unit cell by the SOH of the first unit cell, is calculated as the SOH of the second unit cell. As a result, the SOH can be calculated for all unit cells even if the parameter for degradation diagnosis is not acquired for all unit cells. Consequently, the SOH can be suitably calculated for each unit cell contained in the assembled battery.

The above-described exemplary embodiment of the present disclosure will be further clarified through the detailed description herebelow, with reference to the accompanying drawings.

### First Embodiment

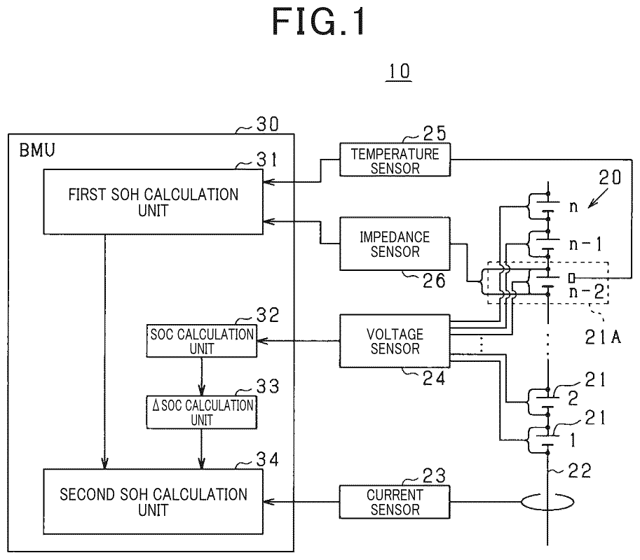

A first embodiment will hereinafter be described with reference to the drawings. According to the present embodiment, a battery system 10 mounted in an electric vehicle such as a hybrid car or an electric car will be described. FIG. 1 is a diagram of a configuration of the battery system 10.

In FIG. 1, the battery system 10 includes an assembled battery 20 and a battery management unit (BMU) 30 serving as a monitoring apparatus that monitors the assembled battery 20. The assembled battery 20 is configured by a plurality of unit cells 21 connected in series. For example, the unit cell 21 may be a lithium-ion battery. The unit cell 21 may be composed of a plurality of battery cells. For example, the plurality of battery cells may be connected in series or in parallel. The assembled battery 20 has n unit cells 21. In FIG. 1, each unit cell 21 is numbered 1, 2, . . . , n−2, n−1, n in order from a negative terminal side of the assembled battery 20. Each unit cell 21 has a similar configuration. A rated capacity of each unit cell 21 is the same.

A current sensor 23 is provided on an electrical path 22 to which each unit cell 21 is connected in series. In addition, the assembled battery 20 is provided with a voltage sensor 24 that detects a voltage across both ends for each unit cell 21. The voltage sensor 24 monitors terminal voltages for all unit cells 21.

In the n unit cells 21, a specific unit cell 21 is provided with a temperature sensor 25 that detects battery temperature and an impedance sensor 26 that detects impedance serving as internal resistance. An impedance detection method of the impedance sensor 26 may be arbitrary. However, for example, the impedance sensor 26 may calculate the impedance based on voltage response when an alternating-current current is applied to the unit cell 21. The impedance may be calculated at a plurality of frequencies.

In the description below, to distinguish between the unit cell 21 (unit cell 21 with sensors) provided with the temperature sensor 25 and the impedance sensor 26, and the unit cell 21 (unit cell 21 without sensors) not provided with these sensors 25 and 26, the unit cell 21 with sensors is also referred to as a first unit cell 21A, and the unit cell 21 without sensors is also referred to as a second unit cell 21B. In the drawings, of the reference numbers 21A and 21B of the unit cell 21, only the reference number 21A is attached to avoid complexity. The unit cell 21 to which the reference number 21A is not attached, among the plurality of unit cells 21, corresponds to the second unit cell 21B.

According to the present embodiment, among the n unit cells 21, the unit cell 21 that has a highest temperature during energization (charging or discharging) of the assembled battery 20 is the first unit cell 21A. Temperature detection by the temperature sensor 25 and impedance detection by the impedance sensor 26 is performed for this first unit cell 21A.

To supplement, among the n unit cells 21, relative temperature differences occur during energization of the assembled battery 20 depending on a structure of an arrangement inside a battery case, positional relationships with a cooling apparatus, and the like. For example, when the unit cells 21 are arranged laterally, side by side, the temperatures of the unit cells 21 are thought to become relatively high near a center of the arrangement, and the temperatures of the unit cells 21 are thought to become relatively low near an end of the arrangement. According to the present embodiment, among the n unit cells 21 shown in FIG. 1, an (n−2)th unit cell 21 is the unit cell 21 that has the highest temperature in the energized state. The (n−2)th unit cell 21 is the first unit cell 21A and the unit cells 21 other than the (n−2)th are the second unit cells 21B.

Here, the first unit cell 21A is merely required to be prescribed from high-temperature cells that have relatively high temperatures while the assembled battery 20 is in the energized state, among the unit cells 21. For example, the first unit cell 21A may be a unit cell 21 that has a high temperature relative to an average temperature of all unit cells 21.

The BMU 30 is an electronic control apparatus that has a microprocessor having a central processing unit (CPU) and various types of memories. Detection signals of the various sensors described above are inputted as appropriate to the BMU 30. The BMU 30 performs various calculation processes related to the assembled battery 20 based on a program stored in the memory. Specifically, the BMU 30 calculates an SOC as an index indicating a storage state of each unit cell 21 based on the terminal voltage of each unit cell 21. In addition, the BMU 30 calculates an SOH as an index indicating a degradation state of each unit cell 21 based on the battery temperature and the impedance of each unit cell 21. The SOH is equivalent to a degradation index indicating a degree of degradation of each unit cell 21. According to the present embodiment, the BMU 30 corresponds to a battery diagnostic apparatus, and the temperature sensor 25 and the impedance sensor 26 correspond to a detection unit that detects parameters for diagnosing degradation of the unit cell 21.

A configuration for calculating the SOH of each unit cell 21 will be described in detail below.

In the battery system 10 according to the present embodiment, the temperature sensor 25 and the impedance sensor 26 are provided only for a specific unit cell 21 (first unit cell 21A) among the plurality of unit cells 21. That is, the parameters for diagnosing degradation can be acquired from only the first unit cell 21A, and the SOH can be calculated based on these diagnostic parameters. In other words, the SOH cannot be calculated based on the diagnostic parameters (battery temperature and impedance) for the second unit cell 21B other than the first unit cell 21A. However, in the assembled battery 20, a change amount of remaining capacity of each unit cell 21 caused by energization corresponds to a product of the SOH, an SOC change amount, and a reference full-charge capacity of the unit cell 21. In this case, in the assembled battery 20 in which the plurality of unit cells 21 are connected in series, the change amounts of remaining capacities of the unit cells 21 are all the same even if the SOH of the unit cells 21 differs. Therefore, the product of the SOH and the SOC change amount is the same for all unit cells 21. In light of this point, according to the present embodiment, the SOH of the second unit cell 21B is calculated based on a ratio of the SOH of the first unit cell 21A, and the SOC change amount (ΔSOC) of the first unit cell 21A and each second unit cell 21B.

That is, the SOC [%] and the SOH [%] of each unit cell 21 are expressed by (Expression 1) and (Expression 2), below. Here, Cr denotes remaining capacity [Ah] of the unit cell 21, Cf denotes actual full-charge capacity [Ah] of the unit cell 21, and Cf0 denotes reference full-charge capacity [Ah] of the unit cell 21.

$$SOC = Cr / Cf \qquad ( Expression 1 )$$

$$SOH = Cr / Cf 0 \qquad ( Expression 2 )$$

In addition, when the remaining capacity Cr of the unit cell 21 changes in accompaniment with energization, a remaining capacity change amount ΔCr is expressed by (Expression 3), below.

$$Δ Cr = Δ SOC \times Cf = Δ SOC \times ( SOH \times Cf 0 ) \qquad ( Expression 3 )$$

In this case, the remaining capacity change amount ΔCr is the same regardless of the SOH of the unit cells 21. Therefore, in a comparison between the first unit cell 21A and the second unit cell 21B, respective (ΔSOC×SOH) are the same.

Furthermore, here, when the SOH is SOH1 and the ΔSOC is ΔSOC1 for the first unit cell 21A, and the SOH is SOH2 and the ΔSOC is ΔSOC2 for the second unit cell 21B, because ΔSOC1×SOH1=ΔSOC2×SOH2, (Expression 4), below, is established.

$$SOH 2 = SOH 1 \times ( Δ SOC 1 / Δ SOC 2 ) \qquad ( Expression 4 )$$

According to the present embodiment, the SOH2 of the second unit cell 21B is calculated using (Expression 4). In this case, the SOH2 of the second unit cell 21B is calculated by referencing the ΔSOC1 and the SOH1 of the first unit cell 21A. That is, as a result of (Expression 4), a value obtained by multiplying a change amount ratio that is a ratio of the SOC change amount (ΔSOC1) of the first unit cell 21A to the SOC change amount (ΔSOC2) of the second unit cell 21B, by SOH1 of the first unit cell 21A is calculated as the SOH2 of the second unit cell 21B.

As shown in FIG. 1, the BMU 30 has a first SOH calculation unit 31, an SOC calculation unit 32, a ΔSOC calculation unit 33, and a second SOH calculation unit 34 as configurations related to SOH calculation.

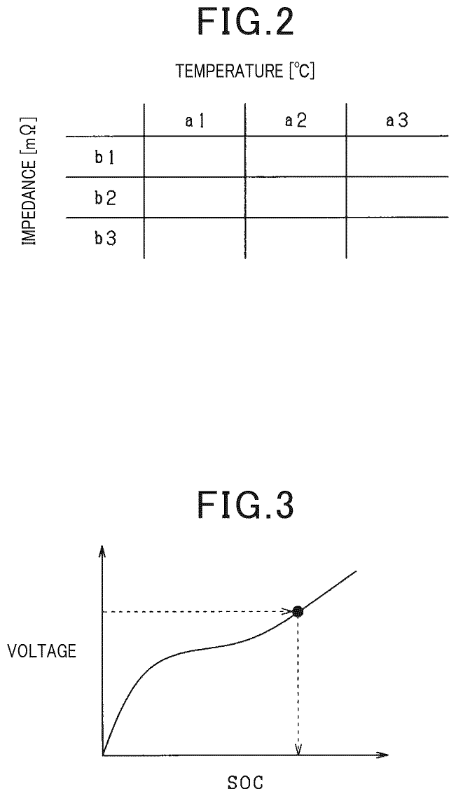

The first SOH calculation unit 31 acquires the battery temperature and the impedance for the first unit cell 21A, and calculates the SOH1 of the first unit cell 21A based on the battery temperature and the impedance. In this case, for example, the SOH1 can be calculated using a correlation map showing a correlation among the battery temperature, the impedance, and the SOH. FIG. 2 shows an example of the correlation map. In the correlation map, SOH values may be prescribed by compatibility or the like. However, instead of the correlation map, the SOH1 can also be calculated using a correlation equation that prescribes the relationship among the battery temperature, the impedance, and the SOH.

The SOC calculation unit 32 acquires the terminal voltage for each unit cell 21 and calculates the SOC for all unit cells 21 based on those terminal voltages. In this case, the SOC calculation unit 32 may calculate the SOC of each unit cell 21 using voltage-SOC characteristics shown in FIG. 3. The voltage obtained as the terminal voltage may be an open circuit voltage (OCV) when the unit cell 21 is not energized. The OCV is preferably a voltage after time for stabilizing the state has elapsed from the end of energization of each unit cell 21. For example, the OCV for each unit cell 21 may be acquired at a timing after an elapse of a predetermined amount of time or more after a power switch of the vehicle is turned off. Alternatively, the OCV for each unit cell 21 may be acquired at a timing before the power switch of the vehicle is turned on, such as when a vehicle door is opened.

The ΔSOC calculation unit 33 calculates the ΔSOC that is the SOC change amount caused by energization of the assembled battery 30 for each unit cell 21, based on the SOC of each unit cell 21 calculated by the SOC calculation unit 32. For example, a difference between an SOC calculated at a current end of vehicle travel and an SOC calculated at a previous end of vehicle travel may be calculated as the ΔSOC.

The second SOH calculation unit 34 calculates the SOH2 of the second unit cell 21B based on the SOH1 of the first unit cell 21A calculated by the first SOH calculation unit 31 and the ΔSOC of each unit cell 21 calculated by the ΔSOC calculation unit 33 using (Expression 4), above. As a result, a value obtained by multiplying a ΔSOC ratio that is a ratio of the ΔSOC1 of the first unit cell 21A to the ΔSOC2 of the second unit cell 21B by the SOH1 of the first unit cell 21A is calculated as the SOH2 of the second unit cell 21B.

Here, the first SOH calculation unit 31 is corresponds to a first calculation unit, the SOC calculation unit 32 and the ΔSOC calculation unit 33 correspond to a second calculation unit, and the second SOH calculation unit 34 corresponds to a third calculation unit.

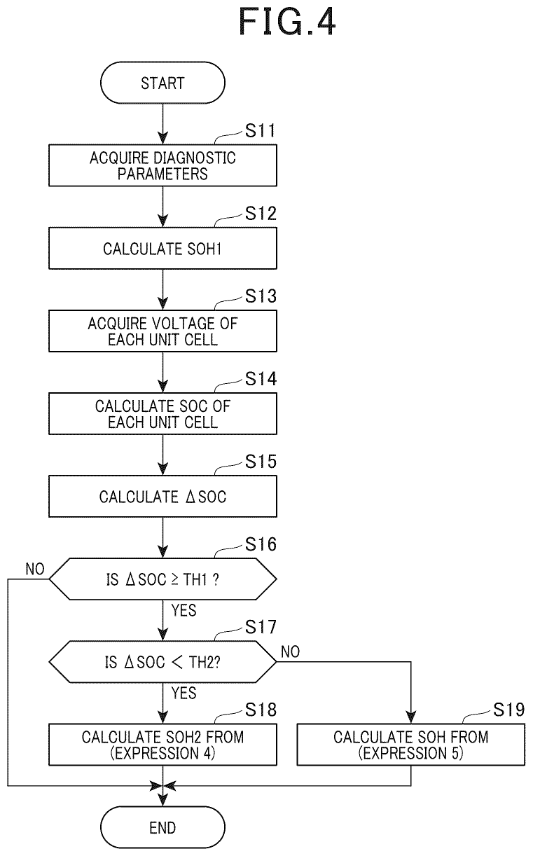

FIG. 4 is a flowchart of steps for calculating the SOH of each unit cell 21. The BMU 30 performs a present process, for example, after turning off the power switch of the vehicle.

In FIG. 4, at step S11, the battery temperature and the impedance of the first unit cell 21A ((n−2)th unit cell 21) that is a high-temperature cell are acquired as diagnostic parameters used for degradation diagnosis. At step S12, for example, the SOH1 of the first unit cell 21A is calculated based on the diagnostic parameters using the correlation map shown in FIG. 2. Here, a calculation timing for the SOH1 may be an arbitrary timing while the power switch is turned on, if acquisition of the diagnostic parameters is possible.

Next, at step S13, the terminal voltages (OCV) of all unit cells 21 are acquired. At subsequent step S14, the SOC is calculated for each unit cell 21 based on the terminal voltage of each unit cell 21, for example, using the voltage-SOC characteristics shown in FIG. 3. The SOC calculated for each unit cell 21 may be stored in a backup memory for each vehicle trip. Also, at step S15, the difference between the SOC calculated at the current end of vehicle travel and the SOC calculated at the previous end of vehicle travel is calculated as the ΔSOC, for each unit cell 21.

At step S16, whether the ΔSOC calculated at step S15 is equal to or greater than a predetermined threshold TH1 is determined. At this time, when the ΔSOC is equal to or greater than the threshold TH1, the present process proceeds to subsequent step S17. When the ΔSOC is less than the threshold TH1, the present process is immediately ended. At step S16, whether the ΔSOC is equal to or greater than the predetermined threshold TH1 may be determined for a specific unit cell 21 prescribed in advance. Alternatively, whether a minimum SOC or a maximum SOC among all unit cells 21 is equal to or greater than the threshold TH1 may be determined (this similarly applies to step S17, described hereafter).

Here, if the ΔSOC that is the difference between the current SOC value and the previous SOC value is less than the threshold TH1, the present process can return to step S15, calculate the difference between the current SOC value and an SOC value preceding the previous value (for example, a second preceding value or a third preceding value) as the ΔSOC, and determine again whether the ΔSOC is equal to or greater than the threshold value TH1 at step S16.

At step S17, whether the ΔSOC is less than a predetermined threshold TH2 is determined. The threshold TH2 is a value greater than the threshold TH1. At this time, when the ΔSOC is less than the threshold TH2, the present process proceeds to step S18. When the ΔSOC is equal to or greater than the threshold TH2, the present process proceeds to step S19.

At step S18, the SOH2 of the second unit cell 21B is calculated based on the SOH1 of the first unit cell 21A calculated at step S12 and the ΔSOC of each unit cell 21 calculated at step S15 using (Expression 4), above.

At step S19, the SOH of the unit cell 21 is calculated for all unit cells 21 based on the ΔSOC of each unit cell 21 calculated at step S15, and a current integrated value from a previous SOC calculation to a current SOC calculation used to calculate the ΔSOC, using (Expression 5), below.

$$SOH = current integrated value / Δ SOC \qquad ( Expression 5 )$$

Here, at step S19, only the SOH2 of the second unit cell 21B may be calculated by (Expression 5), instead of the SOH of all unit cells 21 being calculated by (Expression 5). The current integrated value is calculated by integrating an energizing current for each unit cell 21 in a current integration process (not shown), and is successively stored in the backup memory. In (Expression 5), the current integrated value in a numerator on a right-hand side may be current capacity and the ΔSOC in a denominator on the right-hand side may be (ΔSOC×full-charge capacity).

When determined NO at step S17, the present process may be ended without the SOH2 of the second unit cell 21 being calculated. Here, in FIG. 4, steps S11 and S12 correspond to a first calculation process. Steps S14 and S15 correspond to a second calculation process. Step S18 corresponds to a third calculation process.

According to the present embodiment described in detail above, the following excellent effects can be obtained.

Among the plurality of unit cells 21, the unit cell 21 of which the SOH is calculated based on the parameters for degradation diagnosis is the first unit cell 21A and the unit cell 21 of which the SOH is not calculated is the second unit cell 21B. In addition, the value obtained by multiplying the ΔSOC ratio (change amount ratio) that is the ratio of the ΔSOC1 of the first unit cell 21A to the ΔSOC2 of the second unit cell 21B by the SOH1 of the first unit cell 21A is calculated as the SOH2 of the second unit cell 21B. As a result, calculation of the SOH for all unit cells 21 becomes possible even without the parameters for degradation diagnosis being acquired for all unit cells 21. Consequently, the SOH can be favorably calculated for each unit cell 21 contained in the assembled battery 20.

Among the plurality of unit cells 21, the high-temperature cell is a unit cell that relatively easily degrades and is a unit cell having high sensitivity to degradation. In addition, in the assembled battery 20 in which the plurality of unit cells 21 are connected in series, performance of the assembled battery 20 is rate-limited by the unit cell 21 having a high degree of degradation. Focusing on this point, with the high-temperature cell as the first unit cell 21A, the SOH2 of the second unit cell 21 is calculated based on the ΔSOC ratio (ΔSOC1/ΔSOC2) of the first unit cell 21A (high-temperature cell) and the second unit cell 21B, and the SOH1 of the first unit cell 21A. As a result, degradation diagnosis of the second unit cell 21B can be performed with high accuracy with reference to the unit cell assumed to have a high degree of degradation. Here, because IR drop (voltage drop due to path resistance) that is a factor for errors in the high-temperature cell is small, improved accuracy of SOH can be expected.

When the ΔSOC of the unit cell 21 is greater than a predetermined value, instead of the SOH2 of the second unit cell 21B being calculated using the ΔSOC1 and the SOH1 of the first unit cell 21A (calculation of the SOH by (Expression 4)), calculation of the SOH of each unit cell 21 based on the ΔSOC and the current integrated value (calculation of the SOH by (Expression 5)) is performed. As a result, the SOH of each unit cell 21 can be appropriately calculated regardless of a magnitude of the ΔSOC (SOC change amount).

The following configurations are possible as variation examples according to the present first embodiment.

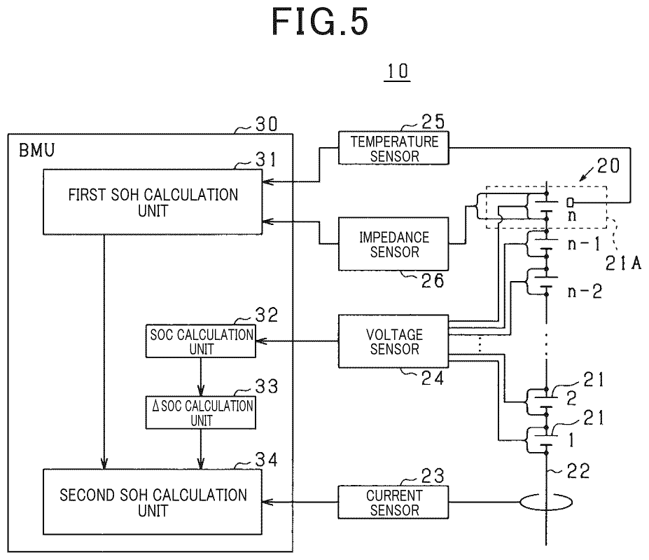

FIG. 5 is a configuration diagram of the battery system 10 in the present variation example. As differences from FIG. 1, in FIG. 5, the configuration is such that, among the n unit cells 21, the unit cell 21 having a lowest temperature during energization (charging or discharging) of the assembled battery 20 is the first unit cell 21A, and temperature detection by the temperature sensor 25 and impedance detection by the impedance sensor 26 are performed for this first unit cell 21A. Specifically, among the n unit cells 21 shown in FIG. 5, the nth unit cell 21 is the unit cell 21 having the lowest temperature while the assembled battery 20 is in the energized state. The nth unit cell 21 is the first unit cell 21A and the unit cells 21 other than the nth are the second unit cells 21B. Here, the first unit cell 21A is merely required to be prescribed from low-temperature cells that are relatively low temperature while the assembled battery 20 is in the energized state. For example, the first unit cell 21A may be a unit cell 21 that has a low temperature relative to the average temperature of all unit cells 21.

Steps for SOH calculation for each unit cell 21 by the BMU 30 are substantially as shown in FIG. 4, described above. To briefly describe the differences, in FIG. 4, at steps S11 and S12, the battery temperature and the impedance are acquired, and the SOH1 is calculated for the first unit cell 21A (nth unit cell 21) that is the low-temperature cell. In addition, at step S18, in (Expression 4), described above, the SOH2 of the second unit cell 21B (unit cell 21 other than nth) is calculated based on the SOH1 of the first unit cell 21A (nth unit cell 21) and the ΔSOC of each unit cell 21.

Among the plurality of unit cells 21, the low-temperature cell has a greater impedance than the high-temperature cell. Therefore, the impedance that is a parameter for degradation diagnosis can be detected with relatively high accuracy. Focusing on this point, the low-temperature cell is the first unit cell 21A, and the SOH2 of the second unit cell 21B is calculated based on the ΔSOC ratio (ΔSOC1/ΔSOC2) of the first unit cell 21A (low-temperature cell) and the second unit cell 21B, and the SOH1 of the first unit cell 21A. As a result, the SOH1 of the first unit cell 21A can be accurately calculated, and degradation diagnosis of the second unit cell 21B can be performed with high accuracy.

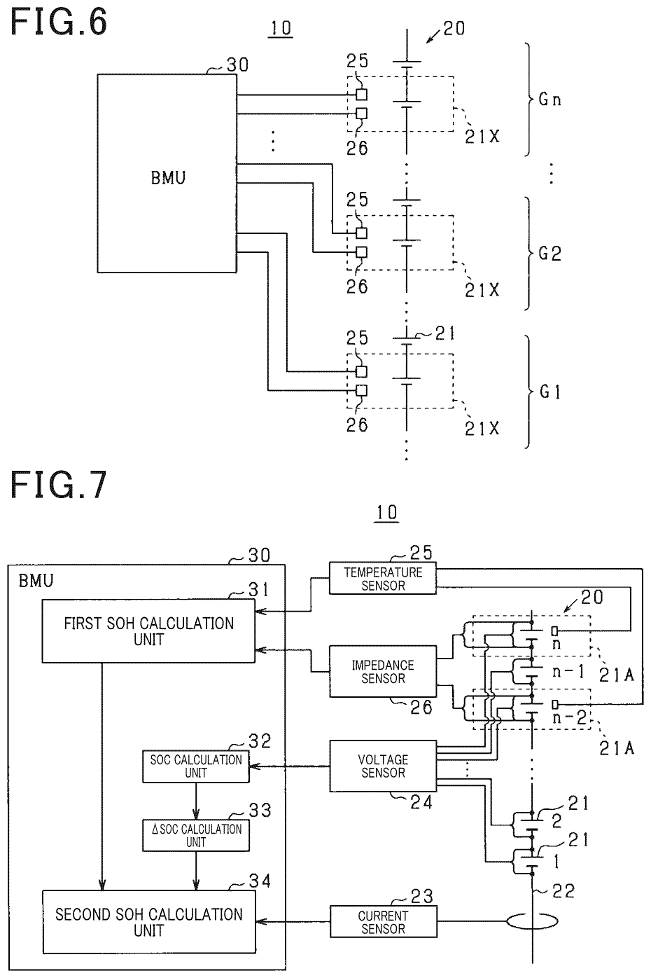

As shown in FIG. 6, the unit cells 21 of the assembled battery 20 may be divided into a plurality of cell groups G1 to Gn of which the temperatures relatively differ while the assembled battery 20 is in the energized state. For each of the cell groups G1 to Gn, a specific unit cell 21X allowing parameter detection by the temperature sensor 25 and the impedance sensor 26 may be prescribed. Here, the specific unit cell 21X may be the high-temperature cell having a relatively high temperature or the low-temperature cell having a relatively low temperature. All that is required is that the specific unit cell 21X be prescribed for each of the cell groups G1 to Gn. In addition, the number of unit cells 21 in each of the cell groups G1 to Gn may be the same or may differ. For example, among the cell groups G1 to Gn, the number of unit cells 21 may be less in the cell group having a large temperature difference between the unit cell 21 with the highest temperature and the unit cell 21 with the lowest temperature, than the cell group having a small temperature difference.

The BMU 30 may perform the process for SOH calculation shown in FIG. 4, described above, with the specific unit cell 21X as the first unit cell 21A, for each of the cell groups G1 to Gn. In this case, the BMU 30 calculates the SOH1 of the first unit cell 21A (specific unit cell 21X) based on the parameters for degradation diagnosis detected for the first unit cell 21A, and calculates the SOH2 of the second unit cell 21B using the SOH1. According to other embodiments below, differences from the first embodiment described above will mainly be described.

### Second Embodiment

FIG. 7 is a configuration diagram of the battery system 10 according to the present embodiment. In FIG. 7, as differences from FIG. 1, the configuration is such that, among the n unit cells 21, the unit cell 21 that has the highest temperature and the unit cell 21 that has the lowest temperature during energization of the assembled battery 20 are the first unit cells 21A. Temperature detection by the temperature sensor 25 and impedance detection by the impedance sensor 26 are performed for these two first unit cells 21A. Specifically, the (n−2)th unit cell 21 is the high-temperature cell that has the highest temperature and the nth unit cell 21 is the low-temperature cell that has the lowest temperature while the assembled battery 20 is in the energized state. These (n−2)th and nth unit cells 21 are the first unit cells 21A. The unit cells 21 other than the (n−2)th and nth unit cells 21 are the second unit cells 21B. Here, the high-temperature cell and the low-temperature cell are merely required to be a high-temperature cell that has a relatively high temperature and a low-temperature cell that has a relatively low temperature while the assembled battery 20 is in the energized state.

According to the present embodiment, each second unit cell 21B is paired with the first unit cell 21A having a small temperature difference while the assembled battery 20 is in the energized state, and the SOH2 of the second unit cell 21B is calculated using the ΔSOC1 and the SOH1 of the paired first unit cell 21A. Here, whether each second unit cell 21B (unit cell 21 other than the (n−2)th and the nth) is paired with the first unit cell 21A on the low-temperature side or the first unit cell 21A on the high-temperature side may be prescribed in advance.

In addition, according to the present embodiment, a method by which the SOH2 of the second unit cell 21B is calculated is changed based on whether an assembled battery temperature Tb that is a temperature of the overall assembled battery 20 is lower or higher than a predetermined temperature. Specifically, when the assembled battery temperature Tb is lower than the predetermined temperature, the low-temperature cell is the first unit cell 21A and the SOH2 of the second unit cell 21B is calculated based on the SOH1 of this first unit cell 21A. Meanwhile, when the assembled battery Tb is higher than the predetermined temperature, each second unit cell 21B is paired with the first unit cell 21A having a small temperature difference, of the first unit cell 21A on the low-temperature side and the first unit cell 21A on the high-temperature side, and the SOH2 of the second unit cell 21B is calculated based on the SOH1 of this first unit cell 21A.

Here, for the assembled battery temperature Tb, a detection value of the temperature sensor 25 provided in any of the n unit cells 21 may be used or, under an assumption that the temperature of the assembled battery 20 has sufficiently decreased after end of use of the assembled battery 20, a detection value of an outside air temperature sensor may be used.

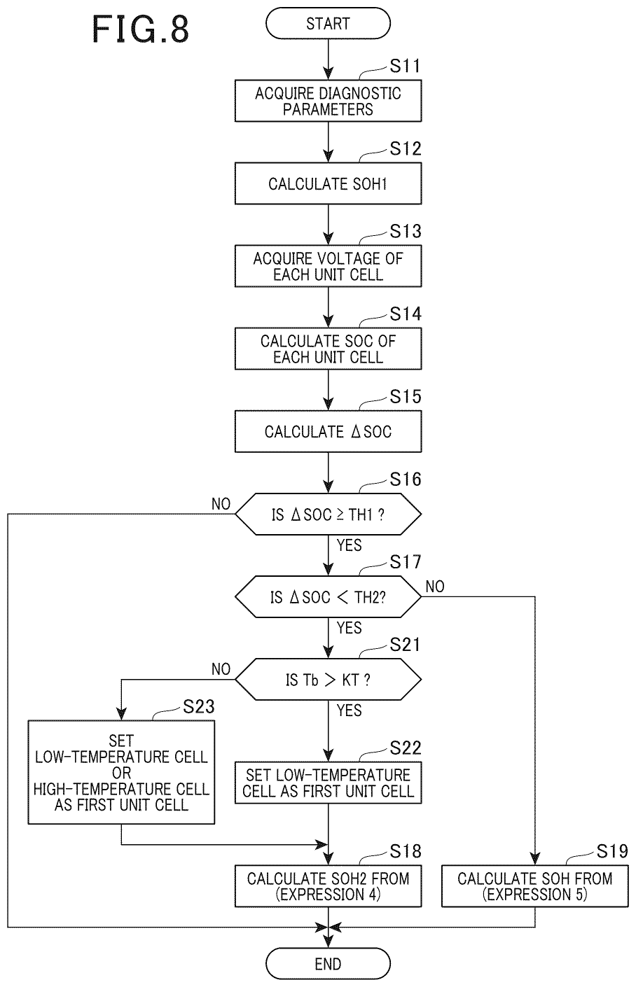

FIG. 8 is a flowchart of an SOH calculation process according to the present embodiment. The present process is performed instead of FIG. 4 by the BMU 30. Here, in FIG. 8, processes similar to those in FIG. 4 are given the same step numbers and detailed descriptions thereof are omitted.

In FIG. 8, at steps S11 and S12, the battery temperature and the impedance are acquired as the parameters used for degradation diagnosis for the two first unit cells 21A, and the SOH1 is calculated based on the diagnostic parameters. At this time, the SOH1 is calculated for each of the first unit cell 21A that is the high-temperature cell and the first unit cell 21A that is the low-temperature cell. Then, at steps S13 to S15, the SOC is calculated based on the terminal voltage (OCV) for each unit cell 21, and the difference between the SOC at the current end of vehicle travel and the SOC at the previous end of vehicle travel is calculated as the ΔSOC. Then, when the ΔSOC is determined to be is equal to or greater than the threshold value TH1 at step S16 and when the ΔSOC is determined to be less than the threshold TH2 at step S17, the process proceeds to step S21.

At step S21, whether the assembled battery temperature Tb is a lower temperature than a predetermined temperature threshold KT is determined. For example, the temperature threshold KT may be 0° C. Then, when the assembled battery temperature Tb is determined to be a lower temperature than the temperature threshold KT, the process proceeds to step S22, and the first unit cell 21A that is the lower-temperature cell (nth unit cell 21) of the two first unit cells 21A is determined as the first unit cell 21A of which the SOH1 is referenced. In addition, when the assembled battery temperature Tb is determined to be a higher temperature than the temperature threshold KT, the process proceeds to step S23, and for each second unit cell 21B, the first unit cell 21A having a smaller temperature difference with the second unit cell 21B, of the low-temperature cell (nth unit cell 21) and the high-temperature cell ((n−2)th unit cell 21), is determined as the first unit cell 21A of which the SOH1 is referenced.

Then, at step S18, the SOH2 of the second unit cell 21B is calculated with reference to the ΔSOC and the SOH1 of the first unit cell 21A determined at steps S21 to S23, and using (Expression 4), described above.

Effects according to the second embodiment described in detail above will be described below.

Because the voltage-SOC characteristics of the assembled battery 20 are temperature-dependent, if the unit cells 21 have temperatures that are close to each other while the assembled battery 20 is in the energized state, the voltage-SOC characteristics are also similar. In this case, if the first unit cell 21A and the second unit cell 21B are paired to be unit cells 21 that have a small temperature difference, SOC errors respectively occurring in the unit cells 21A and 21B are equal. An equal error is applied on both the denominator side and the numerator side of the ΔSOC ratio in (Expression 4), described above. Therefore, the ΔSOC ratio is not easily affected by temperature. In light of this point, the SOH2 of the second unit cell 21B is calculated using the ΔSOC and the SOH1 of the first unit cell 21A having a small temperature difference with the second unit cell 21B while the assembled battery 20 is in the energized state, of the two first unit cells 21A, for each second unit cell 21B. As a result, even if the temperature difference among the unit cells 21 is large in the overall assembled battery 20, calculation accuracy for the SOH can be ensured and the SOH of all unit cells 21 can be appropriately calculated.

When the assembled battery 20 is in a low temperature state, impedance detection accuracy becomes higher for the unit cell 21 on the lower-temperature side among the plurality of unit cells 21, and the calculation accuracy of SOH1 of the first unit cell 21A becomes higher. Meanwhile, when the assembled battery 20 is not in a low temperature state, advantages of using the low temperature cell as reference decrease. Taking this point into consideration, when the assembled battery temperature TB is determined to be a lower temperature than the temperature threshold KT (predetermined temperature), the low-temperature cell is set as the first unit cell 21A, and the SOH2 of the second unit cell 21B is calculated based on the SOH1 of the first unit cell 21A. Meanwhile, when the assembled battery temperature TB is determined to be a higher temperature than the temperature threshold KT, the SOH2 of the second unit cell 21B is calculated using the ΔSOC and the SOH1 of the first unit cell 21A having a smaller temperature difference with the second unit cell 21B for each second unit cell 21B. As a result, the SOH of each unit cell 21 can be appropriately calculated both when the assembled battery 20 is in the low temperature state and not in the low temperature state.

Following configurations are possible as variation examples according to the present second embodiment.

Among the n unit cells 21, three or more unit cells 21 having different battery temperatures during energization of the assembled battery 20 can each be the first unit cell 21A. For example, when three unit cells 21 are the first unit cells 21A, the SOH2 of the second unit cell 21B may be calculated using the ΔSOC and the SOH1 of the first unit cell 21A having a smaller temperature difference with the second unit cell 21B among the three first unit cells 21A, for each second unit cell 21B.

In FIG. 8, the processes at steps S21 and S22 can be omitted. In this case, when the ΔSOC is determined to be equal to or greater than the threshold TH1 at step S16, and the ΔSOC is determined to be less than the threshold TH2 at step S17, the process proceeds to step S23 and the unit cell 21 having the smaller temperature difference with the second unit cell 21B, of the low-temperature cell (nth unit cell 21) and the high-temperature cell ((n−2)th unit cell), is determined as the first unit cell 21A of which the SOH1 is referenced, for each second unit cell 21B. In addition, at subsequent step S18, the SOH2 of the second unit cell 21B is calculates with reference to the ΔSOC and the SOH of the first unit cell 21A determined at step S23 and using (Expression 4), described above.

### Third Embodiment

According to a present embodiment, the configuration is such that all unit cells 21 of the assembled battery 20 are provided with the temperature sensor 25 and the impedance sensor 26. That is, the configuration is such that the battery temperature and the impedance that are diagnostic parameters are calculated for all unit cells 21. According to the present embodiment, when a determination is made that a sensor abnormality has occurred in any of the unit cells 21, whereas the unit cell 21 in which the sensor abnormality has occurred is the second unit cell 21B, the unit cell 21 in which the sensor abnormality is determined to have not occurred is the first unit cell 21A, and the SOH2 of the second unit cell 21B is calculated.

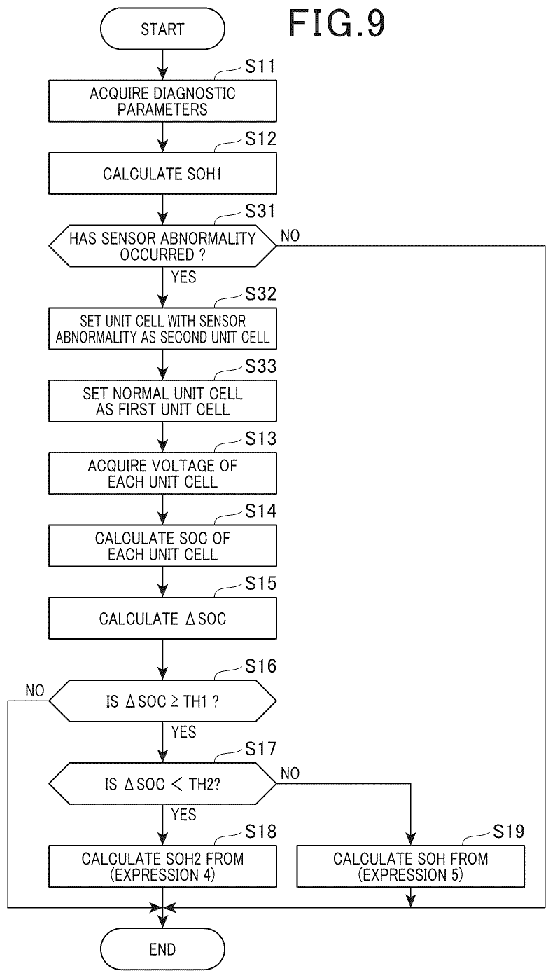

FIG. 9 is a flowchart of an SOH calculation process according to the present embodiment. The present process is performed instead of FIG. 4 by the BMU 30. Here, in FIG. 9, processes similar to those in FIG. 4 are given the same step numbers and detailed descriptions thereof are omitted.

In FIG. 9, at steps S11 and S12, the battery temperature and the impedance are acquired as the parameters used for degradation diagnosis, and the SOH1 is calculated based on the diagnostic parameters for the first unit cell 21A. At this time, all unit cells 21 are set as the first unit cell 21A and the SOH1 is calculated for each unit cell 21.

Then, at step S31, whether an abnormality has occurred in the temperature sensor 25 and the impedance sensor 26 provided in each unit cell 21 is determined. The abnormality determination may be performed by an arbitrary method. However, for example, a determination that a sensor abnormality has occurred may be made when the detection value of the temperature sensor 25 is a value outside a prescribed range or a deviation amount relative to an average value of the detection values in each unit cell 21 is equal to or greater than a predetermined value. Then, if a negative determination is made at step S31, the present process is ended as is. In addition, if an affirmative determination is made at step S31, the process proceeds to step S32.

At step S32, the unit cell 21 in which the sensor abnormality is determined to have occurred is the second unit cell 21B. In addition, at step S33, any of the normal unit cells 21 in which the sensor abnormality is determined to have not occurred is determined to be the first unit cell 21a of which the SOH1 is referenced. Specifically, of the normal unit cells 21, the unit cell 21 having the smallest temperature difference with the unit cell 21 having the sensor abnormality is determined to be the first unit cell 21A of which the SOH1 is referenced. In addition, of the normal unit cells 21, a high-temperature cell that has a relatively high temperature (such as a highest-temperature unit cell 21) or a low-temperature cell that has a relatively low temperature (such as a lowest-temperature unit cell 21) can also be determined as the first unit cell 21A of which the SOH1 is referenced.

Then, at steps S13 to S15, the SOC is calculated based on the terminal voltage (OCV) for each unit cell 21, and the difference between the SOC of the current end of vehicle travel and the SOC of the previous end of vehicle travel is calculated as the ΔSOC. In addition, when the ΔSOC is determined to be equal to or greater than the threshold TH1 at step S16, and the ΔSOC is determined to be less than the threshold TH2 at step S17, the process proceeds to step S18. At step S18, the SOH2 of the second unit cell 21B (that is, the unit cell 21 with the sensor abnormality) is calculated with reference to the ΔSOC1 and the SOH1 of the first unit cell 21A determined at step S33 and using (Expression 4), described above.

According to the third embodiment described in detail above, whether a sensor abnormality has occurred is determined for the temperature sensor 25 and the impedance sensor 26 provided in each unit cell 21. Whereas the unit cell 21 in which the sensor abnormality is determined to have occurred is set as the second unit cell 21B, the unit cell 21 in which the sensor abnormality is determined to not have occurred is set as the first unit cell 21A. Then, the SOH2 of the second unit cell 21B is calculated based on the ΔSOC1 and the SOH1 of the first unit cell 21A in which the sensor abnormality is determined to not have occurred. In this case, in the unit cell 21 for which calculation of SOH had initially been possible based on the sensor detection information, the calculation of SOH can be continuously performed even if the calculation of SOH no longer is possible due to sensor abnormality.

Here, according to the present embodiment, instead of the configuration in which the temperature sensor 25 and the impedance sensor 26 are provided in all unit cells 21 of the assembled battery 20, the configuration may be such that the temperature sensor 25 and the impedance sensor 26 are provided in some, i.e., at least two of the unit cells 21. In this case as well, in a manner similar to that described above, whereas the unit cell 21 in which the sensor abnormality is determined to have occurred is set as the second unit cell 21B, the unit cell 21 in which the sensor abnormality is determined to have not occurred may be set as the first unit cell 21A.

### OTHER EMBODIMENTS

For example, the above-described embodiments may be modified as follows.

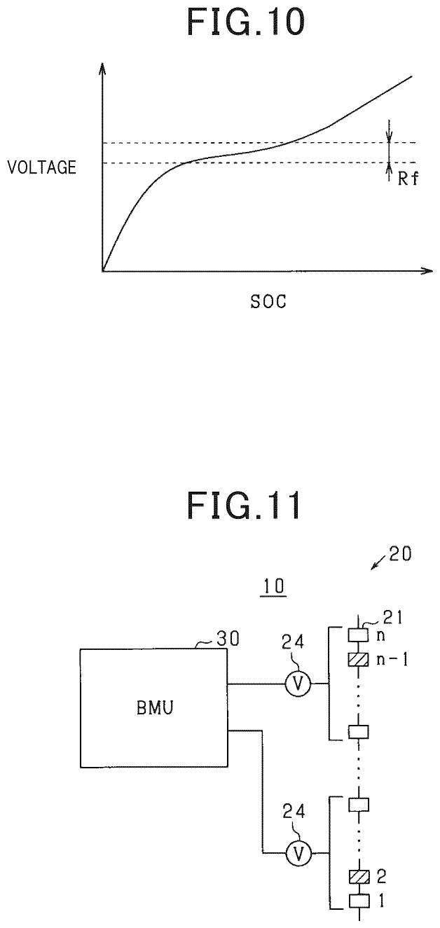

In the SOH calculation process described in FIG. 4 and the like, a condition for permitting or prohibiting calculation of the SOH2 of the second unit cell 21B by (Expression 4), described above, may be prescribed. For example, a prohibition condition prohibiting calculation of the SOH2 of the second unit cell 21B may be prescribed based on a voltage-SOC characteristics line of the unit cell 21 shown in FIG. 10.

In this case, at step S14 in FIG. 4, the BMU 30 calculates the SOC based on the terminal voltage of the unit cell 21 using the voltage-SOC characteristics line, and calculates the ΔSOC (SOC change amount) occurring in accompaniment with energization of the assembled battery 20. In addition, in the voltage-SOC characteristics line shown in FIG. 10, an area in which a slope of the voltage relative to the SOC is equal to or less than a predetermined value is a flat region (plateau region) Rf, and the BMU 30 determines whether the terminal voltage of the unit cell 21 falls within the flat region Rf at step S18 (voltage determining unit). Then, when determined that the terminal voltage falls within the flat region Rf, the BMU 30 does not perform calculation of the SOH2 of the second unit cell 21B. Alternatively, the BMU 30 invalidates the calculation even if the SOH2 of the second unit cell 21B is calculated. That is, when the terminal voltage of the unit cell 21 falls within the flat region Rf, the calculation of the SOH2 of the second unit cell 21B is not made valid.

In the voltage-SOC characteristics line of the unit cell 21, when the terminal voltage of the unit cell 21 falls within the flat region Rf, the change in the SOC is small even if the terminal voltage of the unit cell 21 changes. Therefore, ensuring SOC calculation accuracy is difficult. Therefore, in the voltage-SOC characteristics line of the unit cell 21, when the terminal voltage of the unit cell 21 is determined to fall within the flat region Rf, the configuration is such that calculation of the SOH2 of the second unit cell 21B is not valid. As a result, an issue in that the calculation accuracy of the SOH2 of the second unit cell 21B decreases as a result of the low calculation accuracy of the unit cell 21 can be suppressed.

In addition, the configuration may be such that calculation of the SOH2 of the second unit cell 21B is prohibited (not valid) during a predetermined period immediately after charging and discharging, because the calculation accuracy of the SOC decreases immediately after charging and discharging is performed in the unit cell 21. For example, the BMU 30 may prohibit the calculation of the SOH2 of the second unit cell 21B until a predetermined amount of time elapses when an equalization process (self-balancing process) to equalize the terminal voltages of the unit cells 21 is performed.

As shown in FIG. 11, in the battery system 10, the configuration may be such that a plurality of voltage sensors 24 that detect the terminal voltage of the unit cell 21 is provided, and the terminal voltage of each unit cell 21 is detected by any of the voltage sensors 24. In FIG. 11, a second unit cell 21 and an (n−1)th unit cell 21 are the first unit cells 21A of which the SOH can be calculated by the diagnostic parameters. Here, all that is required is that at least two unit cells 21 be prescribed as the first unit cell 21A. In this case, the configuration may be such that the first unit cell 21A and the second unit cell 21B are paired by the unit cells 21 of which the voltages are detected by the same voltage sensor 24, and the SOH of the second unit cell 21B is calculated based on the SOH1 of the first unit cell 21A.

For example, in the SOH calculation process shown in FIG. 4, the BMU 30 calculates the SOH1 of each first unit cell 21A (step S12). In addition, the BMU 30 calculates the SOC based on the detected voltage of the voltage sensor 24 and calculates the ΔSOC from the SOC before and after the change accompanying energization of the assembled battery 20 (steps S13 to 15). Furthermore, the BMU 30 pairs each second unit cell 21B with the first unit cell 21A of which the voltage is detected by the same voltage sensor 24, and calculates the SOH2 of the second unit cell 21B using the ΔSOC1 and the SOH1 of the first unit cell 21A (step S18).

In the configuration in which the terminal voltages of the unit cells 21 in the assembled battery 20 are detected by the plurality of voltage sensors 24, detection errors are equal when the voltages are detected by the same voltage sensor 24. In this case, if the first unit cell 21A and the second unit cell 21B are paired by the unit cells 21 of which the voltages are detected by the same voltage sensor 24, SOC errors occurring in the unit cells 21A and 21B are equal. An equal error is applied on both the denominator side and the numerator side of the ΔSOC ratio in (Expression 4), described above. Therefore, the ΔSOC ratio is not easily affected by temperature. In light of this point, the SOH2 of the second unit cell 21B is calculated using the ΔSOC and the SOH1 of the first unit cell 21A of which the voltage is detected by the same voltage sensor 24, for each second unit cell 21B. As a result, calculation accuracy for the SOH can be ensured and the SOH of all unit cells 21 can be appropriately calculated.

The configuration may be such that the SOH calculation process in FIG. 4 and the like is performed when the power supply switch of the vehicle is in the on state (the vehicle is in a traveling state). In this case, a plurality of voltages and currents may be calculated for each unit cell 21 during traveling of the vehicle, the OCV may be calculated by an intercept when the voltages and currents are plotted on two-dimensional coordinates, and the SOC of each unit cell 21 may be calculated based on the OCV.

The configuration may be such that only the impedance sensor 26 is provided as the detection unit that detects the diagnostic parameters. In addition, the configuration may be such that only a portion of all unit cells 21 is prescribed as the first unit cells 21A, and impedance detection is performed for the first unit cells 21A.

The battery system 10 is not limited to that mounted in a vehicle. For example, the battery system 10 may be mounted in other moving bodies such as an aircraft or a ship. In addition, the battery system 10 is not limited to that mounted in a moving body and may be a stationary system.

A control unit and a method thereof described in the present disclosure may be actualized by a dedicated computer that is provided such as to be configured by a processor and a memory, the processor being programmed to provide one or a plurality of functions that are realized by a computer program. Alternatively, the control unit and a method thereof described in the present disclosure may be actualized by a dedicated computer that is provided by a processor being configured by a single dedicated hardware logic circuit or more. Still alternatively, the control unit and a method thereof described in the present disclosure may be actualized by a single dedicated computer or more. The dedicated computer may be configured by a combination of a processor that is programmed to provide one or a plurality of functions, a memory, and a processor that is configured by a single hardware logic circuit or more. In addition, the computer program may be stored in a non-transitory computer-readable, tangible storage medium that can be read by a computer as instructions performed by the computer.

Technical ideas extracted from the above-described embodiments are described below.

### [Configuration 1]

A battery diagnostic apparatus (30) that is applicable to a battery system (10) including an assembled battery (20) that includes a plurality of unit cells (21) connected in series and a detection unit (25, 26) that is provided in at least one unit cell among the plurality of unit cells and detects a parameter for degradation diagnosis, the battery diagnostic apparatus calculating a state-of-health indicating a degree of degradation of each unit cell, the battery diagnostic apparatus including: a first calculation unit that acquires the parameter detected by the detection unit for at least one unit cell among the plurality of unit cells and calculates the state-of-health based on the parameter; a second calculation unit that calculates a change amount of a state-of-charge caused by energization, for the plurality of unit cells; and a third calculation unit that, when a unit cell of which the state-of-health is calculated by the first calculation unit among the plurality of unit cells is a first unit cell and a unit cell of which the state-of-health is not calculated among the plurality of unit cells is a second unit cell, calculates a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell.

### [Configuration 2]

The battery diagnostic apparatus according to the configuration 1, in which: the first calculation unit acquires the parameter detected by the detection unit for a high-temperature cell that has a relatively high temperature while the assembled battery is in an energized state, among the plurality of unit cells, and calculates the state-of-health of the high-temperature cell based on the parameter; and the third calculation unit calculates the state-of-health of the second unit cell with the high-temperature cell as the first unit cell.

### [Configuration 3]

The battery diagnostic apparatus according to the configuration 1, in which: the first calculation unit acquires the parameter detected by the detection unit for a low-temperature cell that has a relatively low temperature while the assembled battery is in an energized state, among the plurality of unit cells, and calculates the state-of-health of the low-temperature cell based on the parameter; and the third calculation unit calculates the state-of-health of the second unit cell with the low-temperature cell as the first unit cell.

### [Configuration 4]

The battery diagnostic apparatus according to the configuration 1, in which: the first calculation unit acquires the parameter detected by the detection unit with at least two unit cells among the plurality of unit cells as the first unit cell, and calculates the state-of-health based on the parameter; and the third calculation unit calculates, for each second unit cell, the state-of-health of the second unit cell using the change amount of the state-of-charge of the first unit cell having a small temperature difference with the second unit cell while the assembled battery is in the energized state, of the at least two first unit cells, and the state-of-health.

### [Configuration 5]

The battery diagnostic apparatus according to the configuration 1, in which: the first calculation unit acquires the parameter detected by the detection unit with two or more unit cells including a low-temperature cell that has a relatively low temperature while the assembled battery is in the energized state, among the plurality of unit cells, as the first unit cell, and calculates the state-of-health based on the parameter; the battery diagnostic apparatus includes a temperature determining unit that determines whether an assembled battery temperature that is a temperature of an overall assembled battery is a higher temperature than a predetermined temperature; and the third calculation unit calculates the state-of-health of the second unit cell with the low-temperature cell as the first unit cell, in response to the assembled battery temperature being determined to be a lower temperature than the predetermined temperature and calculates, for each second unit cell, the state-of-health of the second unit cell using the change amount of the state-of-charge of the first unit cell having a small temperature difference with the second unit cell while the assembled battery is in the energized state, among the two or more first unit cells, and the state-of-health, in response to the assembled battery temperature being determined to be a higher temperature than the predetermined temperature.

### [Configuration 6]

The battery diagnostic apparatus according to the configuration 1, in which: the battery system is provided with a plurality of voltage sensors (24) that detect a terminal voltage of each unit cell; the first calculation unit acquires the parameter detected by the detection unit with at least two unit cells among the plurality of unit cells as the first unit cell, and calculates the state-of-health based on the parameter; the second calculation unit calculates the state-of-charge based on the detection voltage of the voltage sensor, and calculates the change amount of the state-of-charge from the states-of-charge before and after change accompanying energization of the assembled battery; and the third calculation unit pairs each second unit cell with the first unit cell of which voltage detection is performed by a same voltage sensor, of the at least two first unit cells, and calculates the state-of-health of the second unit cell using the change amount of the state-of-charge and the state-of-health of the first unit cell.

### [Configuration 7]

The battery diagnostic apparatus according to any one of the configurations 1 to 6, in which: at least two unit cells among the plurality of unit cells in the battery system are provided with the detection unit; the battery diagnostic apparatus includes an abnormality determining unit that determines whether an abnormality has occurred in the detection unit in the unit cell provided with the detection unit; and the third calculation unit calculates the state-of-health of the second unit cell with the unit cell in which an abnormality is determined to have occurred in the detection unit by the abnormality determining unit as the second unit cell, while the unit cell that is provided with the detection unit and in which an abnormality is determined to have not occurred in the detection unit is the first unit cell.

### [Configuration 8]

The battery diagnostic apparatus according to any one of the configurations 1 to 7, further including: a voltage determining unit that determines whether a voltage of the unit cell is within a flat region in which a slope of the voltage relative to the state-of-charge is equal to or less than a predetermined value in a voltage-state-of-charge characteristics line indicating a relationship between the voltage of the unit cell and the state-of-charge, in which the second calculation unit calculates the state-of-charge based on the voltage of the unit cell using the voltage-state-of-charge characteristics line and the change amount of the state-of-charge from the states-of-charge before and after the change accompanying energization of the assembled battery, and the third calculation unit does not make valid calculation of the state-of-health of the second unit cell in response to the voltage of the unit cell being within the flat region.

### [Configuration 9]

The battery diagnostic apparatus according to any one of the configurations 1 to 8, further including: a change amount determining unit that determines whether the change amount of the state-of-charge calculated by the second calculation unit is greater than a predetermined value; and a fourth calculation unit that calculates the state-of-health based on the change amount of the state-of-charge and an integrated value of current flowing to the unit cell during a period in which the change amount of the state-of-charge is calculated, instead by calculation of the state-of-health by the third calculation unit, in response to the change amount of the state-of-charge being determined to be greater than the predetermined value by the change amount determining unit.

While the present disclosure has been described with reference to embodiments thereof, it is to be understood that the disclosure is not limited to the embodiments and constructions. The present disclosure is intended to cover various modification examples and modifications within the range of equivalency. In addition, various combinations and configurations, and further, other combinations and configurations including more, less, or only a single element thereof are also within the spirit and scope of the present disclosure.

### [Configuration 10]

A non-transitory computer-readable storage medium storing therein a program performed by a control apparatus that is applicable to a battery system including an assembled battery that includes a plurality of unit cells connected in series and a detection unit that is provided in at least one unit cell among the plurality of unit cells and detects a parameter for degradation diagnosis, the program causing the control apparatus to calculate a state-of-health indicating a degree of degradation of each unit cell, the program comprising: a first calculation process for acquiring the parameter detected by the detection unit for at least one unit cell among the plurality of unit cells and calculating the state-of-health based on the parameter; a second calculation process for calculating a change amount of a state-of-charge caused by energization, for the plurality of unit cells; and a third calculation process for calculating, when a unit cell of which the state-of-health is calculated by the first calculation unit among the plurality of unit cells is a first unit cell and a unit cell of which the state-of-health is not calculated among the plurality of unit cells is a second unit cell, a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell.

### [Configuration 11]

A battery diagnostic apparatus (30) that is applicable to a battery system (10) including an assembled battery (20) that includes a plurality of unit cells (21) connected in series and a detection unit (25, 26) that is provided in at least one unit cell among the plurality of unit cells and detects a parameter for degradation diagnosis, the battery diagnostic apparatus calculating a state-of-health indicating a degree of degradation of each unit cell, the battery diagnostic apparatus including: at least one of (i) a circuit and (ii) a processor with a memory storing computer program code executable by the processor, the at least one of the circuit and the processor configured to cause the battery diagnostic apparatus to: acquire the parameter detected by the detection unit for at least one unit cell among the plurality of unit cells and calculate the state-of-health based on the parameter; calculate a change amount of a state-of-charge caused by energization, for the plurality of unit cells; and when a unit cell of which the state-of-health is calculated among the plurality of unit cells is a first unit cell and a unit cell of which the state-of-health is not calculated among the plurality of unit cells is a second unit cell, calculate a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell.

### [Configuration 12]

A battery diagnostic method for a battery system (10) including an assembled battery (20) that includes a plurality of unit cells (21) connected in series and a detection unit (25, 26) that is provided in at least one unit cell among the plurality of unit cells and detects a parameter for degradation diagnosis, the battery diagnostic method calculating a state-of-health indicating a degree of degradation of each unit cell, the battery diagnostic method including: acquiring the parameter detected by the detection unit for at least one unit cell among the plurality of unit cells and calculating the state-of-health based on the parameter; calculating a change amount of a state-of-charge caused by energization, for the plurality of unit cells; and when a unit cell of which the state-of-health is calculated among the plurality of unit cells is a first unit cell and a unit cell of which the state-of-health is not calculated among the plurality of unit cells is a second unit cell, calculating a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell.

What is claimed is:

1. A battery diagnostic apparatus that is applicable to a battery system including an assembled battery that includes a plurality of unit cells connected in series and a detection unit that is provided in at least one unit cell among the plurality of unit cells and detects a parameter for degradation diagnosis, the battery diagnostic apparatus calculating a state-of-health indicating a degree of degradation of each unit cell, the battery diagnostic apparatus comprising:
a first calculation unit that acquires the parameter detected by the detection unit for at least one unit cell among the plurality of unit cells and calculates the state-of-health based on the parameter;
a second calculation unit that calculates a change amount of a state-of-charge caused by energization, for the plurality of unit cells; and
a third calculation unit that, when a unit cell of which the state-of-health is calculated by the first calculation unit among the plurality of unit cells is a first unit cell and a unit cell of which the state-of-health is not calculated among the plurality of unit cells is a second unit cell, calculates a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell, wherein:
the first calculation unit acquires the parameter detected by the detection unit for a high-temperature cell that has a relatively high temperature while the assembled battery is in an energized state, among the plurality of unit cells, and calculates the state-of-health of the high-temperature cell based on the parameter; and
the third calculation unit calculates the state-of-health of the second unit cell with the high-temperature cell as the first unit cell.

2. A battery diagnostic apparatus that is applicable to a battery system including an assembled battery that includes a plurality of unit cells connected in series and a detection unit that is provided in at least one unit cell among the plurality of unit cells and detects a parameter for degradation diagnosis, the battery diagnostic apparatus calculating a state-of-health indicating a degree of degradation of each unit cell, the battery diagnostic apparatus comprising:
a first calculation unit that acquires the parameter detected by the detection unit for at least one unit cell among the plurality of unit cells and calculates the state-of-health based on the parameter;
a second calculation unit that calculates a change amount of a state-of-charge caused by energization, for the plurality of unit cells; and
a third calculation unit that, when a unit cell of which the state-of-health is calculated by the first calculation unit among the plurality of unit cells is a first unit cell and a unit cell of which the state-of-health is not calculated among the plurality of unit cells is a second unit cell, calculates a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell, wherein:
the first calculation unit acquires the parameter detected by the detection unit for a low-temperature cell that has a relatively low temperature while the assembled battery is in an energized state, among the plurality of unit cells, and calculates the state-of-health of the low-temperature cell based on the parameter; and
the third calculation unit calculates the state-of-health of the second unit cell with the low-temperature cell as the first unit cell.

3. A battery diagnostic apparatus that is applicable to a battery system including an assembled battery that includes a plurality of unit cells connected in series and a detection unit that is provided in at least one unit cell among the plurality of unit cells and detects a parameter for degradation diagnosis, the battery diagnostic apparatus calculating a state-of-health indicating a degree of degradation of each unit cell, the battery diagnostic apparatus comprising:
a first calculation unit that acquires the parameter detected by the detection unit for at least one unit cell among the plurality of unit cells and calculates the state-of-health based on the parameter;
a second calculation unit that calculates a change amount of a state-of-charge caused by energization, for the plurality of unit cells; and
a third calculation unit that, when a unit cell of which the state-of-health is calculated by the first calculation unit among the plurality of unit cells is a first unit cell and a unit cell of which the state-of-health is not calculated among the plurality of unit cells is a second unit cell, calculates a value obtained by multiplying a change amount ratio that is a ratio of the change amount of the state-of-charge of the first unit cell to the change amount of the state-of-charge of the second unit cell by the state-of-health of the first unit cell, as the state-of-health of the second unit cell, wherein:
the first calculation unit acquires the parameter detected by the detection unit with at least two unit cells among the plurality of unit cells as the first unit cell, and calculates the state-of-health based on the parameter; and
the third calculation unit calculates, for each second unit cell, the state-of-health of the second unit cell using the change amount of the state-of-charge of the first unit cell having a small temperature difference with the second unit cell while the assembled battery is in the energized state, of the at least two first unit cells, and the state-of-health.

4. The battery diagnostic apparatus according to claim 1, wherein:
the first calculation unit acquires the parameter detected by the detection unit with two or more unit cells including a low-temperature cell that has a relatively low temperature while the assembled battery is in the energized state, among the plurality of unit cells, as the first unit cell, and calculates the state-of-health based on the parameter;
the battery diagnostic apparatus includes a temperature determining unit that determines whether an assembled battery temperature that is a temperature of an overall assembled battery is a higher temperature than a predetermined temperature; and
the third calculation unit
calculates the state-of-health of the second unit cell with the low-temperature cell as the first unit cell, in response to the assembled battery temperature being determined to be a lower temperature than the predetermined temperature and
calculates, for each second unit cell, the state-of-health of the second unit cell using the change amount of the state-of-charge of the first unit cell having a small temperature difference with the second unit cell while the assembled battery is in the energized state, among the two or more first unit cells, and the state-of-health, in response to the assembled battery temperature being determined to be a higher temperature than the predetermined temperature.

5. The battery diagnostic apparatus according to claim 1, wherein:
the battery system is provided with a plurality of voltage sensors that detect a terminal voltage of each unit cell;
the first calculation unit acquires the parameter detected by the detection unit with at least two unit cells among the plurality of unit cells as the first unit cell, and calculates the state-of-health based on the parameter;
the second calculation unit calculates the state-of-charge based on the detection voltage of the voltage sensor, and calculates the change amount of the state-of-charge from the states-of-charge before and after change accompanying energization of the assembled battery; and
the third calculation unit pairs each second unit cell with the first unit cell of which voltage detection is performed by a same voltage sensor, of the at least two first unit cells, and calculates the state-of-health of the second unit cell using the change amount of the state-of-charge and the state-of-health of the first unit cell.

6. The battery diagnostic apparatus according to claim 1, wherein:
at least two unit cells among the plurality of unit cells in the battery system are provided with the detection unit;
the battery diagnostic apparatus includes an abnormality determining unit that determines whether an abnormality has occurred in the detection unit in the unit cell provided with the detection unit; and
the third calculation unit calculates the state-of-health of the second unit cell with the unit cell in which an abnormality is determined to have occurred in the detection unit by the abnormality determining unit as the second unit cell, while the unit cell that is provided with the detection unit and in which an abnormality is determined to have not occurred in the detection unit is the first unit cell.

7. The battery diagnostic apparatus according to claim 1, further comprising:
a voltage determining unit that determines whether a voltage of the unit cell is within a flat region in which a slope of the voltage relative to the state-of-charge is equal to or less than a predetermined value in a voltage-state-of-charge characteristics line indicating a relationship between the voltage of the unit cell and the state-of-charge, wherein
the second calculation unit calculates the state-of-charge based on the voltage of the unit cell using the voltage-state-of-charge characteristics line and the change amount of the state-of-charge from the states-of-charge before and after the change accompanying energization of the assembled battery, and
the third calculation unit does not make valid calculation of the state-of-health of the second unit cell in response to the voltage of the unit cell being within the flat region.

8. The battery diagnostic apparatus according to claim 1, further comprising:
a change amount determining unit that determines whether the change amount of the state-of-charge calculated by the second calculation unit is greater than a predetermined value; and
a fourth calculation unit that calculates the state-of-health based on the change amount of the state-of-charge and an integrated value of current flowing to the unit cell during a period in which the change amount of the state-of-charge is calculated, instead by calculation of the state-of-health by the third calculation unit, in response to the change amount of the state-of-charge being determined to be greater than the predetermined value by the change amount determining unit.

9. The battery diagnostic apparatus according to claim 1, wherein:
the first calculation unit acquires the parameter detected by the detection unit with two or more unit cells including a low-temperature cell that has a relatively low temperature while the assembled battery is in the energized state, among the plurality of unit cells, as the first unit cell, and calculates the state-of-health based on the parameter;
the battery diagnostic apparatus includes a temperature determining unit that determines whether an assembled battery temperature that is a temperature of an overall assembled battery is a higher temperature than a predetermined temperature; and
the third calculation unit
calculates the state-of-health of the second unit cell with the low-temperature cell as the first unit cell, in response to the assembled battery temperature being determined to be a lower temperature than the predetermined temperature and
calculates, for each second unit cell, the state-of-health of the second unit cell using the change amount of the state-of-charge of the first unit cell having a small temperature difference with the second unit cell while the assembled battery is in the energized state, among the two or more first unit cells, and the state-of-health, in response to the assembled battery temperature being determined to be a higher temperature than the predetermined temperature.

10. The battery diagnostic apparatus according to claim 2, wherein:
the battery system is provided with a plurality of voltage sensors that detect a terminal voltage of each unit cell;
the first calculation unit acquires the parameter detected by the detection unit with at least two unit cells among the plurality of unit cells as the first unit cell, and calculates the state-of-health based on the parameter;
the second calculation unit calculates the state-of-charge based on the detection voltage of the voltage sensor, and calculates the change amount of the state-of-charge from the states-of-charge before and after change accompanying energization of the assembled battery; and
the third calculation unit pairs each second unit cell with the first unit cell of which voltage detection is performed by a same voltage sensor, of the at least two first unit cells, and calculates the state-of-health of the second unit cell using the change amount of the state-of-charge and the state-of-health of the first unit cell.

11. The battery diagnostic apparatus according to claim 2, wherein:
at least two unit cells among the plurality of unit cells in the battery system are provided with the detection unit;
the battery diagnostic apparatus includes an abnormality determining unit that determines whether an abnormality has occurred in the detection unit in the unit cell provided with the detection unit; and
the third calculation unit calculates the state-of-health of the second unit cell with the unit cell in which an abnormality is determined to have occurred in the detection unit by the abnormality determining unit as the second unit cell, while the unit cell that is provided with the detection unit and in which an abnormality is determined to have not occurred in the detection unit is the first unit cell.

12. The battery diagnostic apparatus according to claim 2, further comprising:
a voltage determining unit that determines whether a voltage of the unit cell is within a flat region in which a slope of the voltage relative to the state-of-charge is equal to or less than a predetermined value in a voltage-state-of-charge characteristics line indicating a relationship between the voltage of the unit cell and the state-of-charge, wherein
the second calculation unit calculates the state-of-charge based on the voltage of the unit cell using the voltage-state-of-charge characteristics line and the change amount of the state-of-charge from the states-of-charge before and after the change accompanying energization of the assembled battery, and
the third calculation unit does not make valid calculation of the state-of-health of the second unit cell in response to the voltage of the unit cell being within the flat region.

13. The battery diagnostic apparatus according to claim 2, further comprising:
a change amount determining unit that determines whether the change amount of the state-of-charge calculated by the second calculation unit is greater than a predetermined value; and
a fourth calculation unit that calculates the state-of-health based on the change amount of the state-of-charge and an integrated value of current flowing to the unit cell during a period in which the change amount of the state-of-charge is calculated, instead by calculation of the state-of-health by the third calculation unit, in response to the change amount of the state-of-charge being determined to be greater than the predetermined value by the change amount determining unit.

14. The battery diagnostic apparatus according to claim 3, wherein:
the first calculation unit acquires the parameter detected by the detection unit with two or more unit cells including a low-temperature cell that has a relatively low temperature while the assembled battery is in the energized state, among the plurality of unit cells, as the first unit cell, and calculates the state-of-health based on the parameter;
the battery diagnostic apparatus includes a temperature determining unit that determines whether an assembled battery temperature that is a temperature of an overall assembled battery is a higher temperature than a predetermined temperature; and
the third calculation unit
calculates the state-of-health of the second unit cell with the low-temperature cell as the first unit cell, in response to the assembled battery temperature being determined to be a lower temperature than the predetermined temperature and
calculates, for each second unit cell, the state-of-health of the second unit cell using the change amount of the state-of-charge of the first unit cell having a small temperature difference with the second unit cell while the assembled battery is in the energized state, among the two or more first unit cells, and the state-of-health, in response to the assembled battery temperature being determined to be a higher temperature than the predetermined temperature.

15. The battery diagnostic apparatus according to claim 3, wherein:
the battery system is provided with a plurality of voltage sensors that detect a terminal voltage of each unit cell;
the first calculation unit acquires the parameter detected by the detection unit with at least two unit cells among the plurality of unit cells as the first unit cell, and calculates the state-of-health based on the parameter;
the second calculation unit calculates the state-of-charge based on the detection voltage of the voltage sensor, and calculates the change amount of the state-of-charge from the states-of-charge before and after change accompanying energization of the assembled battery; and
the third calculation unit pairs each second unit cell with the first unit cell of which voltage detection is performed by a same voltage sensor, of the at least two first unit cells, and calculates the state-of-health of the second unit cell using the change amount of the state-of-charge and the state-of-health of the first unit cell.

16. The battery diagnostic apparatus according to claim 3, wherein:
at least two unit cells among the plurality of unit cells in the battery system are provided with the detection unit;
the battery diagnostic apparatus includes an abnormality determining unit that determines whether an abnormality has occurred in the detection unit in the unit cell provided with the detection unit; and
the third calculation unit calculates the state-of-health of the second unit cell with the unit cell in which an abnormality is determined to have occurred in the detection unit by the abnormality determining unit as the second unit cell, while the unit cell that is provided with the detection unit and in which an abnormality is determined to have not occurred in the detection unit is the first unit cell.

17. The battery diagnostic apparatus according to claim 3, further comprising:
a voltage determining unit that determines whether a voltage of the unit cell is within a flat region in which a slope of the voltage relative to the state-of-charge is equal to or less than a predetermined value in a voltage-state-of-charge characteristics line indicating a relationship between the voltage of the unit cell and the state-of-charge, wherein
the second calculation unit calculates the state-of-charge based on the voltage of the unit cell using the voltage-state-of-charge characteristics line and the change amount of the state-of-charge from the states-of-charge before and after the change accompanying energization of the assembled battery, and
the third calculation unit does not make valid calculation of the state-of-health of the second unit cell in response to the voltage of the unit cell being within the flat region.

18. The battery diagnostic apparatus according to claim 3, further comprising:
a change amount determining unit that determines whether the change amount of the state-of-charge calculated by the second calculation unit is greater than a predetermined value; and
a fourth calculation unit that calculates the state-of-health based on the change amount of the state-of-charge and an integrated value of current flowing to the unit cell during a period in which the change amount of the state-of-charge is calculated, instead by calculation of the state-of-health by the third calculation unit, in response to the change amount of the state-of-charge being determined to be greater than the predetermined value by the change amount determining unit.
